(19) United States
(12) Patent Application Publication
(10) Pub. No.: US 2010/0062588 A1
(43) Pub. Date: Mar. 11, 2010

(54) METHOD OF MANUFACTURING SEMICONDUCTOR SUBSTRATE

(75) Inventor: Yoshio Murakami, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/551,740

(22) Filed: Sep. 1, 2009

(30) Foreign Application Priority Data
Sep. 5, 2008 (JP) 2008-228575

(51) Int. Cl. H01L 21/20

(52) U.S. Cl. 438/481; 257/E21.09

(57) ABSTRACT

A method of manufacturing a semiconductor substrate, in which a silicon layer is provided on a buried oxide film, includes preparing a base substrate having a seed layer of the silicon layer on the buried oxide film with a film thickness equal to or more than 1 nm and equal to or less than 100 nm, and epitaxially growing the seed layer at a temperature equal to or more than 1000° C. and equal to or less than 1300° C. so as to form the silicon layer with a film thickness equal to or more than 1 μm and equal to or less than 20 μm.

### BACKGROUND OF THE INVENTION

1. Field of the Invention

The present invention relates to a method of manufacturing a semiconductor substrate and, more particularly, to a method of manufacturing a silicon substrate including a silicon layer with a film thickness of 1 μm or more on a buried oxide film.

Priority is claimed on Japanese Patent Application No. 2008-228575, filed Sep. 5, 2008, the content of which is incorporated herein by reference.

2. Description of Related Art

In the related art, a SOI wafer is known as a semiconductor substrate capable of manufacturing a high-performance device. A SOI wafer is typically a wafer including a silicon layer (hereinafter, referred to as a SOI layer) on a buried oxide film (hereinafter, referred to as a BOX film) with a film thickness of about 150 to 500 nm. SOI wafers are largely divided by the film thickness of the SOI layer into thick-film SOI wafers and thin-film SOI wafers.

A thick-film SOI wafer is manufactured by bonding together a support wafer having a buried oxide film on a surface thereof and a single-crystal silicon wafer, grinding or polishing the single-crystal silicon wafer and thickening the SOI layer to a predetermined film thickness. In a thick-film SOI wafer, the film thickness of the SOI layer is typically about 5 to 50 μm and the variation in film thickness of the SOI layer is about ±1 μm.

A thin-film SOI wafer is manufactured by implanting oxygen ions into a surface layer of a single-crystal silicon wafer and thermally diffusing the oxygen ions. In a thin-film SOI wafer, the film thickness of the SOI layer is typically about 0.02 to 1 μm and variation in film thickness of the SOI layer is about ±0.01 μm.

Recently, there is a need for a SOI wafer in which the film thickness of a SOI layer is substantially equal to that of the thick-film SOI wafer and variation in film thickness of the SOI layer is about ±0.1 μm (for example, Japanese Patent Unexamined Publication No. 2007-324629).

In a backside illumination type solid imaging device of Japanese Patent Unexamined Publication No. 2007-324629, light is incident from a side in which wires are formed (a front surface side) and the opposite side (a backside) thereof to a photodiode. In this solid imaging device, light is incident to the photodiode without passing through a layer in which the wires are formed so as to realize high sensitivity and low noise. In addition to such a backside illumination type solid imaging device, a SOI wafer having the above-described characteristics is extremely useful in the manufacture of a bipolar device, a power device or the like.

A method for making the film thickness of the SOI layer thicker than that of the thin-film SOI wafer and the variation in film thickness smaller than that of the thick-film SOI wafer, a method for growing an epitaxial film on a SOI layer of a SOI wafer and thickening the SOI layer has been suggested. In this method, since slip dislocation is apt to occur in the SOI wafer, the quality of the SOI wafer deteriorates. As technology for reducing slip dislocation, there is technology disclosed in Japanese Patent Unexamined Publication No. 2007-194539.

In Japanese Patent Unexamined Publication No. 2007-194539, the reflectivity of the heating lamp light from the surface of the SOI wafer when starting the growth of the epitaxial layer is equal to or more than 30% and equal to or less than 80%. Accordingly, the energy of the heating lamp light is efficiently absorbed and the temperature distribution in the SOI wafer becomes uniform so as to reduce the generation of the slip dislocation.

According to the technology of Japanese Patent Unexamined Publication No. 2007-194539, slip dislocation can be reduced. However, with the high performance of recent devices, there is a need for an improvement in the characteristics of the SOI wafer in addition to reducing slip dislocation. Due to the following reasons, in the technology of Japanese Patent Unexamined Publication No. 2007-194539, it is difficult to cope with such a need.

Generally, in order to improve the crystallinity of the SOI layer, epitaxial growth temperature is increased. However, as the epitaxial growth temperature is increased, distortions due to a difference in thermal expansion coefficient between the BOX film and the SOI layer become prominent and these distortions lead to slip dislocation. According to the technology of Japanese Patent Unexamined Publication No. 2007-194539, the temperature distribution can be made uniform, but the distortions due to the difference in the thermal expansion coefficient cannot be solved although the temperature distribution is uniform. Accordingly, even when the technology of Japanese Patent Unexamined Publication No. 2007-194539 is used, it is difficult to guarantee compatibility of the improvement of the crystallinity with the prevention of the slip dislocation.

In particular, in the manufacture of the SOI wafers, metal contamination in the SOI layer becomes prominent as the epitaxial growth temperature is increased. This is because the material gas of the epitaxial film reacts with piping in a supplying path thereof, and a reaction product (metal component) is moved by the material gas and is mixed into the epitaxial film. If an epitaxial film is formed on a wafer having a bulk shape, the metal component in the epitaxial film is diffused throughout the entire wafer. However, in the SOI wafers, the diffusion of the metal component in the epitaxial film is hindered by the BOX film and thus the metal component is accumulated in the epitaxial film. The accumulation of the metal component is a unique problem in the manufacture of the SOI wafers, but there is no detailed countermeasure against the problem. Accordingly, it is difficult to guarantee compatibility of the improvement of the crystallinity with the prevention of the metal contamination.

The present invention is contrived to solve the above-described problems. An object of the present invention is to provide a method of manufacturing a semiconductor substrate capable of preventing slip dislocation and of improving characteristics thereof.

### SUMMARY OF THE INVENTION

A method of manufacturing a semiconductor substrate, in which a silicon layer is provided on a buried oxide film, includes preparing a base substrate having a seed layer of the silicon layer on the buried oxide film with a film thickness equal to or more than 1 nm and equal to or less than 100 nm, and epitaxially growing the seed layer at a temperature equal to or more than 1000° C. and equal to or less than 1300° C. so as to form the silicon layer with a film thickness equal to or more than 1 μm and equal to or less than 20 μm.

The film thickness of the general buried oxide film is about 150 nm. However, if the film thickness of the buried oxide film is set to be equal to or more than 1 nm and equal to or less than 100 nm as described above, distortions due to heat between the buried oxide layer and the seed layer decrease and thus slip dislocation due to these distortions decrease remarkably. Accordingly, the seed layer can be epitaxially grown under a high-temperature condition without causing slip dislocation. In particular, the seed layer is epitaxially grown at a temperature equal to or more than 1000° C. and equal to or less than 1300° C. such that a silicon layer with good crystallinity can be formed. According to the epitaxial growth method, the film thickness of a silicon layer can be controlled with high accuracy, and thus a silicon layer can be formed with the film thickness equal to or more than 1 μm and equal to or less than 20 μm and variation in film thickness equal to or more than ±0.1 μm.

In addition, since the film thickness of the buried oxide film is equal to or more than 1 nm and equal to or less than 100 nm, it is possible to form a silicon layer with remarkable good characteristics for the following reasons.

The index representing the characteristics of the silicon layer includes the lifetime of carriers. As the lifetime lengthens, the silicon layer can satisfactorily function as an active layer. The better the crystallinity of the silicon layer, the longer the lifetime. As metal contamination remarkably increases, the lifetime shortens. If epitaxial growth is performed under high-temperature conditions, the crystallinity of the silicon layer is good, but metal contamination remarkably increases. This is because gas used in the epitaxial growth is active.

For example, a material gas such as dichlorosilane has a corrosion property. Accordingly, in the high-temperature conditions, there is substantial corrosion of metal contained in the piping for supplying gas or the like. The metal component generated by corrosion is moved into a film forming chamber by the material gas such that the amount of metal component mixed into the film during the epitaxial growth increases. In particular, in a semiconductor substrate having a buried oxide film, the diffusion of the metal component to a lower layer of the buried oxide film is interrupted by the buried oxide film. Accordingly, the metal component is accumulated in the epitaxial film and thus metal contamination becomes remarkable.

The present inventor carried out research on controlling the film thickness of the buried oxide film so as to achieve compatibility of good crystallinity with a reduction in metal contamination. As a result, it was found that, if the film thickness of the buried oxide film is set to be equal to or more than 1 nm and equal to or less than 100 nm, the metal component passes through the buried oxide film and diffuses to the lower layer thereof. In particular, it can be seen that good crystallinity and a reduction in metal contamination are compatible by epitaxially growing the seed layer at a temperature equal to or more than 1000° C. and equal to or less than 1300° C. According to the present invention, since a good silicon layer can be formed while slip dislocation can be prevented, it is possible to manufacture a semiconductor substrate capable of achieving a high-performance device.

The film thickness of the buried oxide film of the base substrate may be equal to or more than 5 nm and equal to or less than 80 nm, and the seed layer may be epitaxially grown at a temperature equal to or more than 1050° C. and equal to or less than 1150° C. Although the detailed description is given in “DETAILED DESCRIPTION OF THE INVENTION”, the film thickness of the buried oxide film is equal to or more than 80 nm and the seed layer is epitaxially grown at a temperature equal to or more than 1050° C. and equal to or less than 1150° C. such that the lifetime of the carriers in the silicon layer becomes 500 μs or more and the number of metal ions per unit area, which are contained in the silicon, becomes 5×10⁹ cm⁻² or less. Accordingly, it is possible to obtain a semiconductor substrate capable of coping with the manufacture of most devices such as bipolar devices, power devices, and devices sensitive to noise due to metal contamination.

In addition, by setting the film thickness of the buried oxide film to be equal to or more than 5 nm, it is possible to ensure the process tolerance of the buried oxide film during the manufacture of a device and to manufacture semiconductor substrates capable of coping with various methods of device manufacturing.

The base substrate may be manufactured by an ion implantation separation method.

According to the ion implantation separation method such as Smart Cut method (registered trademark), it is possible to easily obtain a base substrate having a seed layer with variation in film thickness of ±0.01 μm or less. Accordingly, it is possible to manufacture a semiconductor substrate with good silicon layer film thickness accuracy by using the base substrate manufactured by the ion implantation separation method.

The base substrate may be manufactured by a SIMOX method. In this case, the base substrate may be manufactured by a Modified Low Dose (MLD) method. In the base substrate, a surface layer of the substrate manufactured by a SIMOX method with a thickness equal to or more than 20 nm may be removed by polishing.

According to the SIMOX method, there is no gap generated between the buried oxide film and the seed layer, unlike with the bonding method. Accordingly, it is possible to epitaxially grow the seed layer with good crystallinity and to form a silicon layer with good crystallinity.

In particular, by using the base substrate manufactured by the MLD method of the SIMOX method, it is possible to satisfactorily achieve a buried oxide film with quality equal to that of a thermal oxide film. The base substrate manufactured by the SIMOX method may cause periodic roughness in a surface layer. If 20 nm or more of the surface layer is removed by low-speed polishing such as touch polishing, a flat seed layer without roughness is obtained and thus a silicon layer with good film thickness accuracy and good crystallinity can be formed.

In the forming of the silicon layer, the silicon layer may be formed by removing 20 nm or more of the surface layer after epitaxially growing the seed layer.

By this configuration, it is possible to remove a portion which causes roughness or a portion with low crystallinity on the surface layer of the epitaxially grown film and to form a silicon layer with good film thickness accuracy and good crystallinity.

According to the present invention, it is possible to manufacture a semiconductor substrate having a silicon layer with a film thickness equal to or more than 1 μm and equal to or less than 20 μm and variation in film thickness of ±0.1 μm or less. The manufactured semiconductor substrate, the crystallinity of the silicon layer becomes good, slip dislocation and metal contamination are reduced, and the lifetime of the carriers is remarkably improved. By manufacturing a device using the semiconductor substrate manufactured by the present invention, it is possible to reduce leakage current or noise in the device and to obtain a high-performance device.

### BRIEF DESCRIPTION OF THE DRAWINGS

FIGS. 1A to 1D are cross-sectional views showing a method of manufacturing a semiconductor substrate according to the present invention.

FIGS. 2A and 2B are tables respectively showing the presence or absence of slip dislocation and a metal contamination amount.

FIG. 3 is a table showing the influence of the film thickness of a BOX film and an epitaxial growth temperature on slip dislocation.

FIG. 4 is a graph showing the influence of the film thickness of a BOX film and an epitaxial growth temperature on the lifetime of a carrier.

FIGS. 5A and 5B are graphs showing a relationship between a polishing amount and the number of defects, and the polishing amount and a haze level.

### DETAILED DESCRIPTION OF THE INVENTION

Hereinafter, an embodiment of the present invention will be described, but the technical range of the present invention is not limited to the following embodiment. In the following description, various types of structures are exemplified using the drawings, but, in order to facilitate the understanding of the characteristic portions of the structures, the dimensions or the scales of the structures of the drawings may be different from those of the actual structures. In the present embodiment, a surface layer of a thin-film SOI wafer (base substrate) is thickened so as to manufacture a SOI wafer (semiconductor substrate).

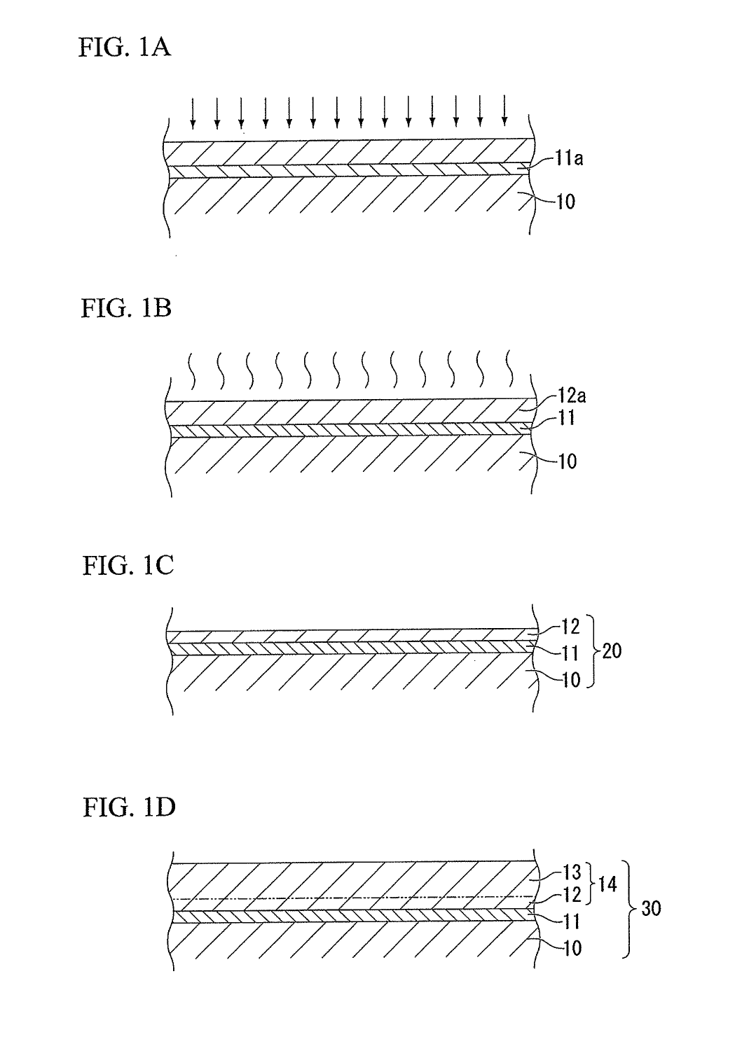

FIGS. 1A to 1D are cross-sectional views showing a method of manufacturing a semiconductor substrate according to an embodiment of the present invention.

In order to manufacture a SOI wafer, a thin-film SOI wafer having a seed layer made of single-crystal silicon on a buried oxide film (hereinafter, referred to as a BOX film) is prepared. As the thin-film SOI wafer, a wafer manufactured by a bonding method, a SIMOX method or the like may be used and a product manufactured by these methods may be used.

The bonding method is a method for bonding two silicon wafers. After an oxide film is formed on a surface of a silicon wafer by a thermal oxidization method or the like, the two silicon wafers are bonded together.

In addition, any one of the silicon wafers is thickened such that the oxide film becomes a BOX film. As the bonding method, there is an ion implantation separation method such as a Smart Cut method (registered trademark).

The ion implantation separation method is a method for implanting hydrogen ions into a silicon wafer and separating the silicon wafer along a layer, into which the hydrogen ions are implanted, so as to perform thickening. According to this method, the seed layer made of single-crystal silicon with a high-accuracy film thickness may be left on the BOX film. Variation in film thickness of the seed layer may be equal to or less than ±0.01 μm.

In the present embodiment, the thin-film SOI wafer is manufactured using a modified low dose method (hereinafter, referred to as an MLD method) which is one of SIMOX methods, and is used in a base substrate. In addition, according to the SIMOX method, since the BOX film can be formed with a high-accuracy depth of the silicon wafer, it is possible to provide a seed layer with a high-accuracy film thickness on the surface of the silicon wafer.

In order to manufacture the thin-film SOI wafer by the MLD method, first, as shown in FIG. 1A, oxygen ions are implanted into the silicon wafer 10. The silicon wafer 10 can be, for example, obtained by machining silicon manufactured by a CZ method in a wafer shape. A p-type impurity such as boron (B) or an n-type impurity such as phosphorous (P) is added to the silicon wafer 10.

The oxygen ion implantation is performed by primary ion implantation and secondary ion implantation. The primary ion implantation is performed, for example, in conditions with a substrate temperature equal to or more than 300° C. (preferably 400° C. to 650° C.), implantation energy at acceleration energy of 140 to 220 KeV (preferably 170 KeV) and a dose amount of 2×10 cm to 4×10¹⁷ cm⁻² (preferably 2.5×10¹⁷ cm⁻²). The secondary ion implantation is performed without heating the silicon wafer 10 in conditions with a dose amount of 2×10¹⁵ cm⁻² ( 1/100 of the primary ion implantation). Accordingly, a high-concentration layer 11a, which is made of silicon containing a high concentration of oxygen ions, is formed in the silicon wafer 10.

Next, as shown in FIG. 1B, the silicon wafer 10 into which oxygen ions are implanted is subjected to a heating treatment. In more detail, first, in an Ar atmosphere including 30 to 60% of oxygen, an Internal Thermal Oxidation (ITOX) treatment is performed at a substrate temperature of 1290 to 1380° C. for about 5 to 40 hours. After the ITOX treatment, in an Ar atmosphere including 0.5 to 4% of oxygen and about 0.3% of dichloroethylene (DCE), an annealing treatment is performed at a substrate temperature of 1290 to 1380° C. for about 5 to 40 hours. Accordingly, the oxygen ions contained in the high-concentration layer 11a are thermally diffused to become a BOX film 11. The film thickness of the BOX film 11 can be controlled by adjusting the implantation energy or the dose amount in the oxygen ion implantation. In the present invention, the film thickness of the BOX film 11 is equal to or more than 1 nm and equal to or less than 100 nm, preferably equal to or more than 5 nm and equal to or less than 80 nm, and more preferably equal to or more than 15 nm and equal to or less than 25 nm.

Next, as shown in FIG. 1C, a surface layer 12a of the silicon wafer 10 is removed by touch polishing (polishing). In detail, polishing is performed by remarkably reducing the polishing speed by the selection of polishing slurry or the adjustment of polishing pressure such that a thickness portion of 20 nm or more is removed from the surface of the silicon wafer 10 of the surface layer 12a. Roughness may occur on the surface layer 12a according to the SIMOX method, but the surface layer 12a of the silicon wafer 10 can be made highly flat by the touch polishing. In this way, the thin-film SOI wafer 20 can be obtained which the seed layer 12 has made of single crystal on the BOX film 11.

In addition, the film thickness of the seed layer 12 is set to 0.02 to 1 μm by adjusting the polishing amount of the touch polishing or the implantation depth of the oxygen ions.

Next, as shown in FIG. 1D, the seed layer 12 of the thin-film SOI wafer 20 is epitaxially grown. In detail, a film forming apparatus using an epitaxial growth method is used. The film forming apparatus includes a film forming chamber having a susceptor for mounting the thin-film SOI wafer 20, a gas supplying device for supplying material gas into the film forming chamber, an atmosphere control device for controlling the atmosphere of the film forming chamber, a temperature control device for controlling the temperature of the thin-film SOI wafer 20 and the like.

In order to epitaxially grow the seed layer 12, first, the thin-film SOI wafer 20 is mounted on the susceptor in the film forming chamber. In addition, the thin-film SOI wafer 20 is heated to a predetermined substrate temperature and the material gas is supplied into the film forming chamber. In the present invention, the substrate temperature is set to be equal to or more than 1000° C. and equal to or less than 1300° C. and preferably equal to or more than 1050° C. and equal to or less than 1150° C. In this way, the material gas supplied into the film forming chamber chemically reacts, silicon is deposited on the seed layer 12 while continuing the crystallinity of the seed layer 12, and an epitaxial film 13 made of silicon is formed.

The material gas supplied into the film forming chamber generally includes a metal component such as iron, nickel or copper. This metal component is generated because the material gas corrodes gas piping in a supply path such as the gas piping of the material gas. The metal component is moved into the film forming chamber by using the material gas as carrier gas and is mixed into the film which is being epitaxially grown. As the substrate temperature is increased, the amount of mixed metal component is increased by the activation of the material gas.

Even in the present embodiment, the metal component is mixed into the epitaxial film 13. However, in the present invention, since the film thickness of the BOX film 11 is set to be equal to or more than 1 nm and equal to or less than 100 nm, the mixed metal component is diffused to a lower layer of the BOX film 11 via the seed layer 12 and the BOX film 11. Accordingly, it is possible to reduce the amount of metal component left in the epitaxial film 13 without accumulating the metal component in the epitaxial film 13.

In the present invention, since it is possible to reduce the amount of metal component left in the epitaxial film 13, the substrate temperature can be increased to a degree that the epitaxial film 13 with good crystallinity is achieved while reducing the residual amount of the metal component. Accordingly, it is possible to form the epitaxial film 13 with good crystallinity.

The seed layer 12 may be distorted since increasing the substrate temperature causes a difference in linear expansion between the BOX film 11 and the seed layer 12, and these distortions may cause slip dislocation in the epitaxial film 13. However, in the present invention, since the film thickness of the BOX film 11 is set to be equal to or more than 1 nm and equal to or less than 100 nm, the distortions are reduced so as to be negligible and thus slip dislocation is prevented from occurring in the epitaxial film 13.

As described above, the seed layer 12 is epitaxially grown so as to form a SOI layer 14 including the seed layer 12 and the epitaxial film 13 with a film thickness equal to or more than 1 μm and equal to or less than 20 μm. In this way, a SOI wafer 30 can be obtained.

Next, the characteristics of the SOI wafer (semiconductor substrate) which can be obtained by the present invention will be described.

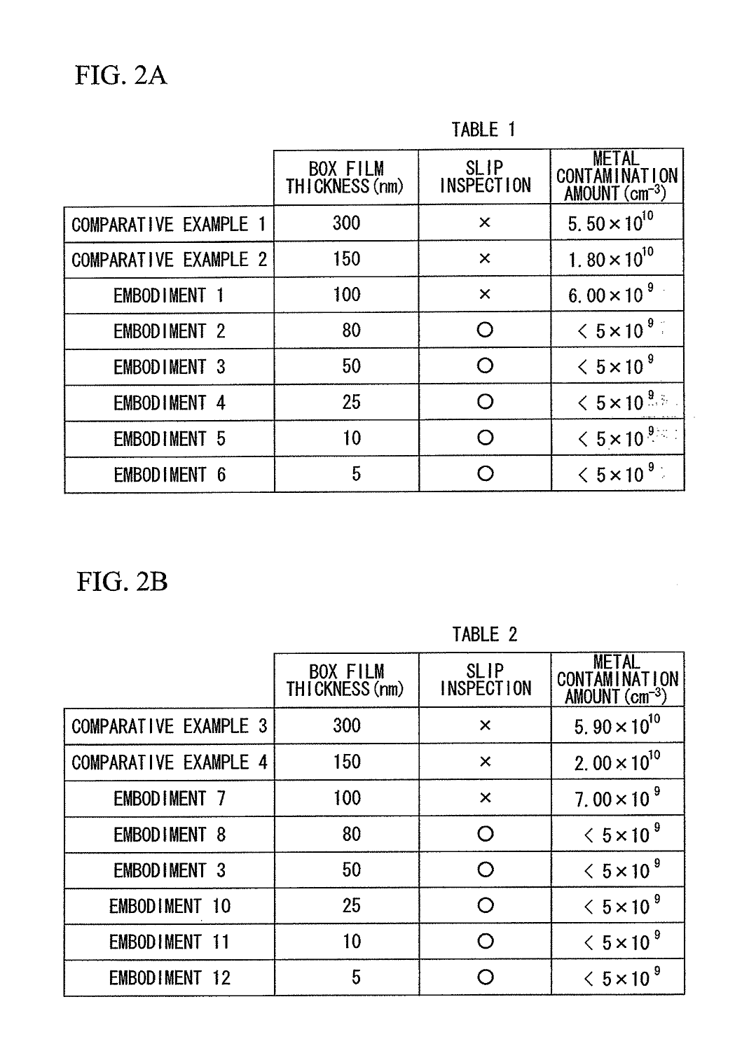

FIGS. 2A and 2B are tables showing the presence or absence of slip dislocation and a metal contamination amount with respect to the SOI wafers of comparative examples and the SOI wafers of embodiments. In Comparative Examples 1 to 4 and Embodiments 1 to 12 shown in FIGS. 2A and 2B, the film thickness of the seed layer is 90 nm and the substrate temperature in the epitaxial growth is 1100° C.

With respect to the presence or absence of slip dislocation, laser light was irradiated to the formed SOI layer and diffused light was MAP-observed and determined by using a haze measurement mode of a particle counter. In FIGS. 2A and 2B, O in the slip inspection column indicates that no pattern was detected in the inspection region of the SOI layer, that is, that there was no slip dislocation. In addition, × in the slip inspection column indicates that slip dislocation was detected.

With respect to the metal contamination amount, the SOI layer was melted in a mixture solution of hydrofluoric acid and nitric acid, and the amount of iron contained in the mixture solution was measured. FIGS. 2A and 2B show the number of iron atoms per unit area which were contained in the SOI layer. In the current state, a SOI wafer with a metal contamination amount of 1.0×10¹⁰ cm⁻² or less may be used for manufacturing most devices. In addition, in a device sensitive to the current value flowing in the SOI layer, such as a backside illumination type solid imaging device, since the metal component may cause the accuracy deterioration of the current value or noise, the 801 wafer with a metal contamination amount of 5.0×10⁹ cm² or less is preferably used for manufacturing the device.

All of Comparative Examples 1 and 2 and Embodiments 1 to 6 shown in Table 1 of FIG. 2A use the thin-film SOI wafer manufactured by the MLD method and are different in the film thickness of the BOX film. The film thickness of the BOX film is 300 nm in Comparative Example 1, 150 nm in comparative Example 2, 100 nm in Embodiment 1, 80 nm in Embodiment 2, 50 nm in Embodiment 3, 25 nm in Embodiment 4, 10 nm in Embodiment 5, and 5 nm in Embodiment 6.

As can be seen from FIG. 2A, in Comparative Examples 1 and 2 in which the film thickness of the BOX film is equal to or more than 150 nm, slip dislocation is detected and the metal contamination amount exceeds 1.0×10¹⁰ cm⁻².

In Embodiment 1 in which the film thickness of the BOX film is 100 nm, slip dislocation is reduced compared with Comparative Examples 1 and 2, but slip dislocation is still detected. The metal contamination amount is a good value of 1.0×10¹⁰ cm⁻² or less. Accordingly, it can be seen that Embodiment 1 of the present invention is a SOI wafer better than Comparative Examples 1 and 2.

In Embodiments 2 to 6 in which the film thickness of the BOX film is 80 nm or less, slip dislocation is not detected and the metal contamination amount is 5.0×10⁹ cm⁻² or less.

Accordingly, it can be seen that Embodiments 2 to 6 of the present invention are SOI wafers better than Comparative Examples 1 and 2.

All Comparative Examples 3 and 4 and Embodiments 7 to 12 shown in Table 2 of FIG. 2B use the thin-film SOI wafer manufactured by the Smart Cut method (registered trademark) and are different in the film thickness of the BOX film. The film thickness of the BOX film is 300 nm in Comparative Example 3, 150 nm in comparative Example 4, 100 nm in Embodiment 7, 80 nm in Embodiment 8, 50 nm in Embodiment 9, 25 nm in Embodiment 10, 10 nm in Embodiment 11, and 5 nm in Embodiment 12.

As can be seen from FIG. 2B, even when the thin-film SOI wafer manufactured by the Smart Cut method (registered trademark) is used, in Comparative Examples 3 and 4 in which the film thickness of the BOX film is equal to or more than 150 nm, slip dislocation is detected and the metal contamination amount exceeds 10×10¹⁰ cm⁻².

Embodiment 7 of the present invention is a SOI wafer better than Comparative Examples 3 and 4 in that the metal contamination amount is 1.0×10¹⁰ cm⁻² or less. In addition, Embodiments 8 to 12 of the present invention are SOI wafers better than Comparative Examples 3 and 4 in that both the slip inspection and the metal contamination amount are excellent.

As described above, it can be seen that a good SOI wafer can be obtained by applying the present invention, in the bonding method such as the SIMOX method or the Smart Cut method (registered trademark).

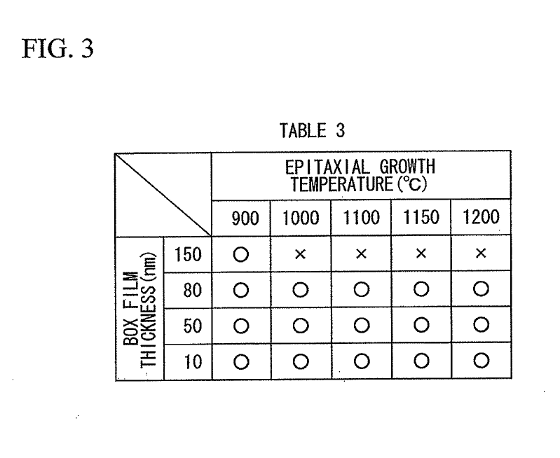

FIG. 3 is a table showing the result of inspecting the presence or absence of slip dislocation by systematically changing the film thickness of the BOX film and the substrate temperature (epitaxial growth temperature) during the epitaxial growth. In addition, a wafer manufactured by the SIMOX method is used as the thin-film SOI wafer. The film thickness of the BOX film is set; 10 nm, 50 nm, 80 nm and 150 nm, and the epitaxial growth temperature is set; 900° C., 1000° C., 1100° C., 1150° C. and 1200° C. The presence or absence of slip dislocation was determined by using the haze measurement mode of the particle counter, similar to the above-described method.

As shown in Table 3 of FIG. 3, if the epitaxial growth temperature is 900° C., the slip dislocation is not detected when the film thickness of the BOX film is any one of 10 nm to 150 nm. This is because the distortions in the seed layer generated during the epitaxial growth due to the difference in the thermal expansion coefficient between the seed layer and the BOX film is too small to cause slip dislocation. If the epitaxial growth temperature is 1000° C. or more, slip dislocation is detected when the film thickness of the BOX film is 150 nm. This is because when the epitaxial growth temperature is more increased than at 900° C., the influence of the difference in the thermal expansion coefficient is remarkably increased, and the distortions in the seed layer is increased so as to cause slip dislocation.

Meanwhile, if the film thickness of the BOX film is 80 nm or less, slip dislocation is not detected even when the epitaxial growth temperature is set to 1000° C. or more. Accordingly, it can be seen that the epitaxial growth temperature can be increased while preventing slip dislocation, by applying the present invention.

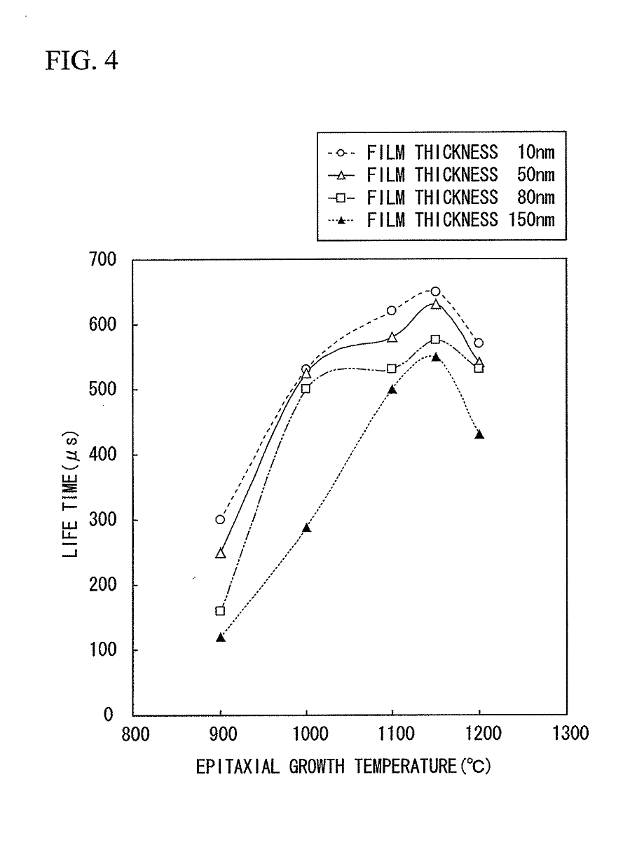

FIG. 4 is a graph showing the result of measuring the lifetime of a carrier in a SOI wafer manufactured by the same condition as Table 3 of FIG. 3. In the graph of FIG. 4, a horizontal axis denotes the substrate temperature in the epitaxial growth and a vertical axis denotes the lifetime. In addition, in the graph of FIG. 4, data is connected by a smooth line in each of the film thicknesses of the BOX film.

The value of the lifetime shown in the graph of FIG. 4 is a value measured by a photoconductive attenuation method. In detail, laser light was irradiated onto a SOI layer so as to generate minority carriers and the lifetime was measured as a time constant of the recombination of the minority carriers. The time constant of the recombination of the minority carriers was obtained by a time variation in the reflection intensity of microwaves.

The lifetime is the index showing the characteristics of the SOI layer. As the lifetime is increased, good characteristics are obtained. For example, as the lifetime of the SOI layer is increased, leakage current is decreased. The lifetime increases as the crystallinity of the SOI layer is improved and increases as the metal contamination amount is decreased. A SOI wafer having a SOI layer with a lifetime of 500 μs or more is very useful in the manufacture of a high-performance device.

As shown in the graph of FIG. 4, when the lifetimes are compared with the film thickness of the BOX film, it can be seen that the lifetime increases as the film thickness of the BOX film is decreased. In particular, a difference in lifetime between the film thickness of 150 nm and the film thickness of 80 nm is remarkable. This is because the film thickness of the BOX film is set to 80 nm or less such that the metal contamination amount left in the SOI layer is reduced and thus the lifetime is remarkably improved.

As the film thickness of the BOX film is decreased, the lifetime increases, but process tolerance in the manufacture of the device using the SOI wafer decreases. In order to satisfy the condition that insulation breakdown is not caused in the BOX film due to plasma or the like, the BOX film functions as an etching stopper, and the film thickness accuracy of the BOX film can be secured, the film thickness of the BOX film is 5 nm or more and is preferably 15 nm or more. From the above-described viewpoint, the film thickness of the BOX film is preferably equal to or more than 5 nm and equal to or less than 80 nm and more preferably equal to or more 15 nm and equal to or less than 25 nm.

When focusing on the epitaxial growth temperature, the lifetime is maximized at the epitaxial growth temperature of about 1150° C. in any of the SOI wafers in which the film thickness of the BOX film is equal to or more than 10 nm and equal to or less than 150 nm. This is because, up to about 1150° C., the crystallinity of the SOI layer improves as the epitaxial growth temperature is increased. The effect of improving the crystallinity of the SOI layer is saturated at about 1150° C. and, at 1150° C. or more, the lifetime is decreased by the increase of the metal contaminated amount. Accordingly, it can be seen that the lifetime is maximized by setting the epitaxial growth temperature to be equal to and more than 1050° C. and equal to or less than 1150° C., and a good SOI wafer with the lifetime of 500 μs or more is obtained.

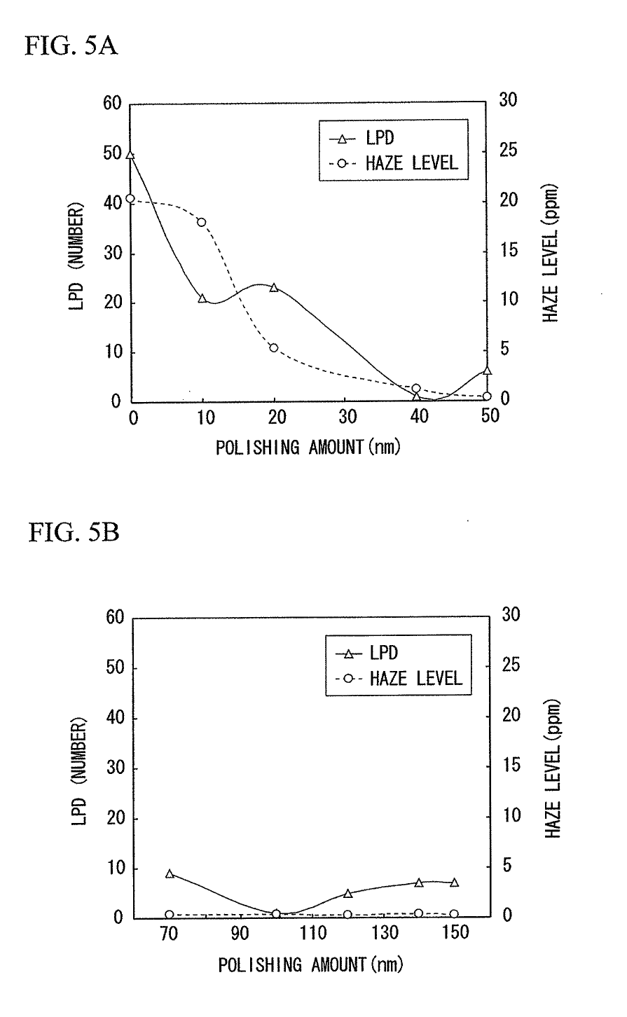

FIG. 5A is a graph showing a relationship between the polishing amount of the touch polishing and the number of defects, and the polishing amount and the haze level. The data of the graph shown in FIG. 5A uses the base substrate made by removing a portion of the surface layer of the thin-film SOI wafer manufactured by the SIMOX method by the touch polishing. The film thickness of the BOX film is 10 nm, the film thickness of the SOI layer before the touch polishing is 100 nm, and the epitaxial growth temperature is 1100° C. The left vertical axis of the graph denotes LPD and the right axis of the graph denotes the haze level. The horizontal axis of the graph denotes the film thickness (polishing amount) reduced by polishing.

As shown in the graph of FIG. 5A, when the touch polishing is performed, the LPD and the haze level are reduced, compared with the case where the touch polishing is not performed (the case where the polishing amount is 0 nm). In particular, it can be seen that the effect for reducing the number of defects and the haze level becomes remarkable by setting the polishing amount to 20 nm or more, and thus a good SOI wafer is obtained.

FIG. 5B is a graph showing the relationship between the polishing amount of the touch polishing and the number of defects, and the polishing amount and the haze level, similar to the graph of FIG. 5A. FIG. 5B shows a SOI wafer manufactured by setting the film thickness of the SOI layer before the touch polishing to 200 nm. As shown in the graph of FIG. 5B, even when the film thickness of the SOI layer before the touch polishing is set to 200 nm, the number of defects and the haze level are reduced by performing the touch polishing. When the polishing amount is 40 nm or more as shown in FIG. 5A, the LPD and the haze level are reduced by the same degree as when the polishing amount is 70 nm or more as shown in FIG. 5B. Accordingly, it can be seen that the number of defects and the haze level are reduced when the polishing amount is 20 nm or more and, in particular, the efficient effect can be obtained if the polishing amount is 40 nm or more.

In the method of manufacturing the semiconductor substrate of the present invention, since the film thickness of the buried oxide film (BOX film) is equal to or more than 1 nm and equal to or less than 100 nm, slip dislocation is prevented and the metal contamination amount is reduced In the related art, if the epitaxial growth temperature is increased, slip dislocation is apt to occur and the metal contamination amount increases. However, according to the present invention, since such a problem is solved, the epitaxial temperature can be increased and thus the crystallinity of the SOI layer can be improved. In the SOI wafer which can be obtained by the present invention, since the metal contamination amount is reduced and crystallinity is improved, the lifetime of the carriers remarkably increases.

The SOI wafer according to the present invention can be used for manufacturing a device with high voltage tolerance such as a bipolar device or a power device because the film thickness of the SOI layer is equal to or more than 1 μm and equal to or less than 20 μm. In the manufactured device with high voltage tolerance, the lifetime of the carriers of the SOI layer is remarkably increased such that the leakage current is remarkably reduced, and low power consumption is realized. The SOI wafer according to the present invention can be used for manufacturing a device sensitive to noise, such as a backside illumination type solid imaging device. The manufactured device has high performance with high sensitivity because the metal contamination amount is reduced.

Although the polishing due to the touch polishing is performed before the epitaxial growth in the above-described embodiment, an epitaxially grown film may be polished. Even when the touch polishing is performed after the epitaxial growth, the same effect as when the touch polishing is performed before the epitaxial growth can be obtained. In addition, the touch polishing may be performed before and after the epitaxial growth.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of manufacturing a semiconductor substrate in which a silicon layer is provided on a buried oxide film, the method comprising:
preparing a base substrate having a seed layer of the silicon layer on the buried oxide film with a film thickness equal to or more than 1 nm and equal to or less than 100 nm; and
epitaxially growing the seed layer at a temperature equal to or more than 1000° C. and equal to or less than 1300° C. so as to form the silicon layer with a film thickness equal to or more than 1 μm and equal to or less than 20 μm.

2. The method according to claim 1, wherein:
the film thickness of the buried oxide film of the base substrate is equal to or more than 5 nm and equal to or less than 80 nm, and
the seed layer is epitaxially grown at a temperature equal to or more than 1050° C. and equal to or less than 1150° C.

3. The method according to claim 1, wherein the base substrate is manufactured by an ion implantation separation method.

4. The method according to claim 1, wherein the base substrate is manufactured by a SIMOX method.

5. The method according to claim 4, wherein the base substrate is manufactured by a Modified Low Dose (MLD) method.

6. The method according to claim 4, wherein, in the base substrate, a surface layer of the substrate manufactured by a SIMOX method with a thickness equal to or more than 20 nm is removed by polishing.

7. The method according to claim 1, wherein, in the forming of the silicon layer, the silicon layer is formed by removing the surface layer with a thickness equal to or more than 20 nm after epitaxially growing the seed layer.
